(19) United States
(12) Patent Application Publication
(10) Pub. No.: US 2025/0095999 A1
(43) Pub. Date: Mar. 20, 2025

(54) MANUFACTURING METHOD FOR SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Takeyuki SUZUKI, Kaga Ishikawa (JP)

(21) Appl. No.: 18/419,281

(22) Filed: Jan. 22, 2024

(30) Foreign Application Priority Data
Sep. 14, 2023 (JP) 2023-149072

(51) Int. Cl. H01L 21/304; H01L 21/02; H01L 21/311; H01L 21/683

(52) U.S. Cl. CPC H01L 21/304; H01L 21/02274; H01L 21/0243; H01L 21/31111; H01L 21/6836; H01L 2221/68327; H01L 2221/68386

(57) ABSTRACT

A manufacturing method for a semiconductor device according to an embodiment includes forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area, providing a dicing tape on the semiconductor wafer on the first surface side, dividing the semiconductor wafer into a first member of the ring-shaped convex area and the slope area and a second member of the concave area by cutting the semiconductor wafer, and peeling off the first member of the ring-shaped area and the slope area from the dicing tape.

### CROSS-REFERENCE TO RELATED APPLICATION

This application is based upon and claims the benefit of priority from Japanese Patent Application No. 2023-149072, filed on Sep. 14, 2023, the entire contents of which are incorporated herein by reference.

### FIELD

Embodiments described herein relate generally to a manufacturing method for a semiconductor device.

### BACKGROUND

Power semiconductor devices designed for power control, including semiconductor devices such as MOSFET (Metal-Oxide-Semiconductor Field-Effect-Transistor) and IGBT (Insulated Gate Bipolar Transistor) which are used for wide range fields such as power generation and transmission, rotating machines such as pumps and blowers, power supplies for communication systems and factories, railroads with AC motors, electric vehicles, and household electrical appliances, are being developed.

Typically, semiconductor devices are thinned from semiconductor wafers to a desired thickness. Thinning methods include the TAIKO process, wet etching, and dry etching.

### BRIEF DESCRIPTION OF THE DRAWINGS

FIG. 1 is a flowchart for a manufacturing method for a semiconductor device according to an embodiment;

FIG. 2 is a schematic cross-sectional diagram for a manufacturing method for a semiconductor device according to an embodiment;

FIG. 3 is a schematic process diagram of top view for a manufacturing method for a semiconductor device according to an embodiment;

FIG. 4 is a schematic cross-sectional diagram for a manufacturing method for a semiconductor device according to an embodiment;

FIG. 5 is a schematic cross-sectional diagram for a manufacturing method for a semiconductor device according to an embodiment;

FIG. 6 is a schematic cross-sectional diagram for a manufacturing method for a semiconductor device according to an embodiment;

FIG. 7 is a schematic cross-sectional diagram for a manufacturing method for a semiconductor device according to an embodiment;

FIG. 8 is a flowchart for a manufacturing method for a semiconductor device according to an embodiment;

FIG. 9 is a schematic cross-sectional diagram for a manufacturing method for a semiconductor device according to an embodiment;

FIG. 10 is a schematic cross-sectional diagram for a manufacturing method for a semiconductor device according to an embodiment;

FIG. 11 is a schematic cross-sectional diagram for a manufacturing method for a semiconductor device according to an embodiment;

FIG. 12 is a schematic cross-sectional diagram for a manufacturing method for a semiconductor device according to an embodiment;

FIG. 13 is a schematic cross-sectional diagram for a manufacturing method for a semiconductor device according to an embodiment;

FIG. 14 is a schematic cross-sectional diagram for a manufacturing method for a semiconductor device according to an embodiment;

FIG. 15 is a schematic cross-sectional diagram for a manufacturing method for a semiconductor device according to an embodiment;

FIG. 16 is a schematic cross-sectional diagram for a manufacturing method for a semiconductor device according to an embodiment;

FIG. 17 is a schematic cross-sectional diagram for a manufacturing method for a semiconductor device according to an embodiment;

FIG. 18 is a schematic cross-sectional diagram for a manufacturing method for a semiconductor device according to an embodiment;

FIG. 19 is a schematic cross-sectional diagram for a manufacturing method for a semiconductor device according to an embodiment;

FIG. 20 is a schematic cross-sectional diagram for a manufacturing method for a semiconductor device according to an embodiment; and

FIG. 21 is a partial schematic cross-sectional diagram of a semiconductor wafer and a first insulating layer according to an embodiment.

### DETAILED DESCRIPTION

A manufacturing method for a semiconductor device according to an embodiment includes forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area, providing a dicing tape on the semiconductor wafer on the first surface side, dividing the semiconductor wafer into a first member of the ring-shaped convex area and the slope area and a second member of the concave area by cutting the semiconductor wafer, and peeling off the first member of the ring-shaped area and the slope area from the dicing tape.

Hereinafter, embodiments will be described in detail with reference to the drawings. In the following description, the same symbols are applied to the same or similar components (members/elements), and the explanation may be omitted for components that have been described once.

### First Embodiment

A manufacturing method for a semiconductor device according to a first embodiment includes forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area (first step), providing a dicing tape on the semiconductor wafer on the first surface side (second step), dividing the semiconductor wafer into a first member of the ring-shaped convex area and the slope area and a second member of the concave area by cutting the semiconductor wafer (third step), and peeling off the first member of the ring-shaped area and the slope area from the dicing tape (fourth step).

In the embodiments, a specific type of the semiconductor device and a specific structure of the semiconductor device is not limited. The semiconductor device of the embodiments is, for example, an integrated circuit, a diode, a transistor, and the like. The semiconductor device of the embodiments is, for example, FET (Field Effect Transistor), MOSFET (Metal Oxide Semiconductor Field Effect Transistor), IGBT (Insulated Gate Bipolar Transistor), HEMT (High Electron Mobility Transistor), SBD (Schottky Barrier Diode), and the like.

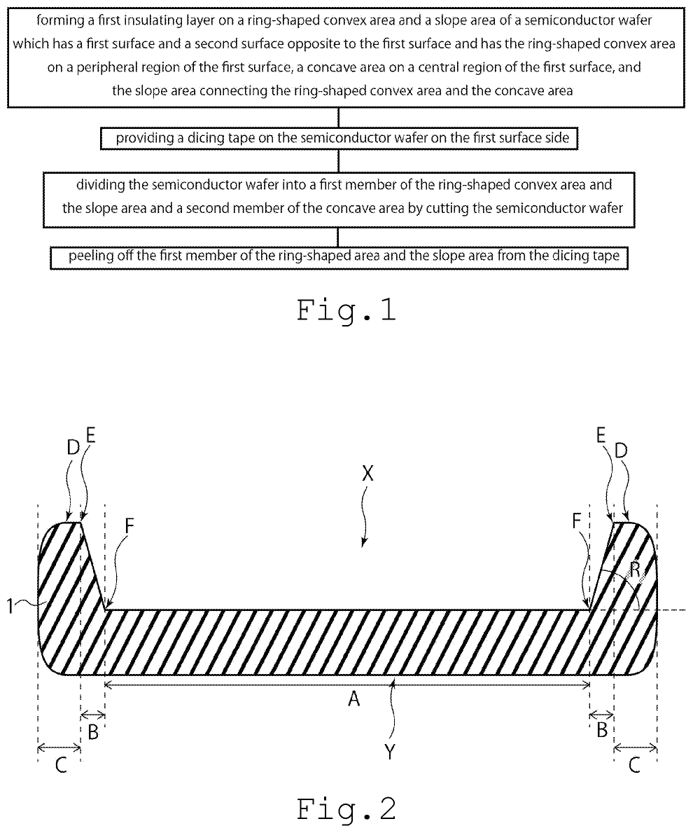

FIG. 1 is a flowchart for a manufacturing method for a semiconductor device according to the first embodiment. FIG. 2 to FIG. 7 show schematic cross-sectional diagrams and a schematic diagram of top view for a manufacturing method for the semiconductor device according to the first embodiment.

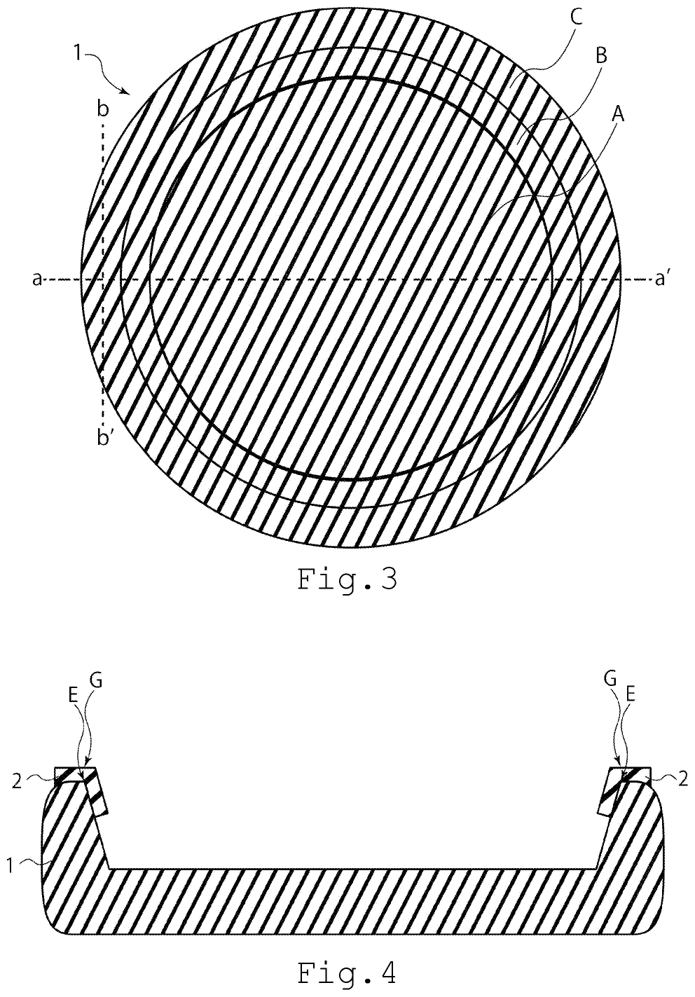

The step of forming the first insulating layer 2 on the ring-shaped convex area C and the slope area B of the semiconductor wafer 1 which has the first surface X and the second surface Y opposite to the first surface X and has the ring-shaped convex area C on the peripheral region of the first surface X, the concave area A on the central region of the first surface X, and the slope area B connecting the ring-shaped convex area C and the concave area A (first step) will be described with reference to the schematic cross-sectional diagram of FIG. 2, the schematic diagram of top view of FIG. 3, and the schematic cross-sectional diagram of FIG. 4 In the first and other embodiments, each schematic cross-sectional diagram is, for example, a cross-sectional diagram of a-a′ of the schematic diagram of top view of FIG. 3.

The first insulating layer 2 is formed on the ring-shaped convex area C and the slope area B of the semiconductor wafer 1 on the first surface X side.

The semiconductor wafer 1 is a member that a semiconductor element region is formed on a substrate whose center area is thinned with, for example, TAIKO process, wet-etching, dry-etching, or the like. The semiconductor wafer 1 is, for example, a circular wafer.

The semiconductor wafer 1 includes the concave area A, the slope area B, and the ring-shaped convex area C from center side to periphery. The slope area B connects the concave area A and the ring-shaped convex area C.

A surface of the semiconductor wafer 1 where the concave area A exists is designated as the first surface X (back side). A surface of the semiconductor wafer 1 which is opposite to the first surface X is designated as the second surface Y (front surface).

The semiconductor element region is formed in the concave area of A wafer the semiconductor 1. The semiconductor wafer 1 is not particularly limited to Si (Silicon), SiC (Silicon Carbide), GaN (Gallium Nitride), or the others. A surface of the concave area A is flat or approximately flat. It is preferable that the concave area A has no protrusions in an outer area (a connecting edge F between the concave area A and the slope area B has circular shape or approximately circular shape preferably).

Since the peripheral area of the semiconductor wafer 1 is thick, the semiconductor wafer 1 has high strength even if the concave area A located at center of the semiconductor wafer 1 is thinned. Since the semiconductor wafer 1 has high strength, forming the semiconductor element region, pads (electrode pads), and the others can be processed easily.

In the first embodiment, electrodes of the semiconductor device on the semiconductor wafer 1 on the first surface X and the second surface Y is not shown, but the electrodes may be formed on the semiconductor wafer 1 on the first surface X or/and the second surface Y before the first step or between the first step and the second step.

The ring-shaped convex area C whose thickness is thicker than a thickness of the concave area A exists on the periphery of the semiconductor wafer 1. The semiconductor wafer 1 has so-called rim shape. A flat surface D or/and an approximately flat surface D exists on the ring-shaped convex area C on the slope area B side. It is preferable that the ring-shaped convex area C has no protrusions on the center side (an interface (connecting edge) E between the ring-shaped convex area C and the slope area B has circular shape or approximately circular shape preferably). The flat surface D or the approximately flat surface D is a surface that excludes a curved surface portion on the periphery of the ring-shaped convex area C. The flat surface D or/and the approximately flat surface D may include roughness which may be formed when the concave area A is formed.

The slope area B on a center side is connected to the concave area A. The slope area B on a peripheral side is connected to the ring-shaped convex area C. It is preferable that the slope area B on a center side is in direct contact with the concave area A. It is preferable that the slope area B on a peripheral side is in direct contact with the ring-shaped convex area C. A slope angle R (taper angle) of the slope area B is an angle of a surface (a slope surface) of the slope area B relative to a surface of the concave area A. The slope angle R can be adjusted when the concave area A is formed.

The slope angle R is preferably 20 [°] or more and 75 [°] or less, and more preferably 30 [°] or more and 60 [°] or less. When the slope angle R is small, a volume of the concave area A tends to small and a non-effective area for the semiconductor device may increase. When the slope angle R is large, the effective area for the semiconductor device can be increased. If the slope angle R is close to a right angle, it is not preferable to make it difficult to form the first insulating layer 2.

The slope area B on the first surface X side preferably includes such as a surface of a truncated cone. The surface of the slope area B on the first surface X side may include fine roughness. The slope area B on the first surface X may include one or more curved surfaces and/or one or more surfaces including one or more steps from the ring-shaped convex area C to the concave area A.

A member shown in FIG. 2 of the schematic cross-sectional diagram is obtained by forming the first insulating layer 2 on the semiconductor wafer 1 shown in FIG. 1 of the schematic cross-sectional diagram. The insulating layer 2 can be formed by deposited by low-temperature plasma-enhanced chemical vapor deposition (plasma-enhanced chemical vapor deposition) on the first surface X entirely and processed with lithography with mask. An inkjet printed layer, a thermosetting resin layer, a seal shaped into the first insulating layer 2, and a coated film can be also used for the first insulating layer 2. When the inkjet printed layer, the thermosetting resin layer, the seal shaped into the first insulating layer 2, or the coated film is used for the first insulating layer 2, these layers are heated or sintered preferably.

When the first insulating layer 2 is formed by low-temperature plasma-enhanced chemical vapor deposition, it is preferable that a temperature of the semiconductor wafer 1 is 200 [° C.] or less.

It is preferable that the first insulating layer 2 is an inorganic insulating layer. It is preferable that the first insulating layer 2 is a SiO₂ layer, a SiN layer, or a The first insulating layer 2 may be a laminate SiON layer. of two or more layers selected from the group consisting of a SiO₂ layer, a SiN layer, and a SiON layer. The first insulating layer 2 can include an organic material, for example, a resin or the others.

The first insulating layer 2 is formed on the surface of the ring-shaped convex area C on the first surface X side and the slope area B on the first surface X side. The first insulating layer 2 is preferably formed on the interface (edge (un-rounded corner) or corner (rounded corner)) between the ring-shaped convex area C and the slope area B.

The first insulating layer 2 adheres to the dicing tape 3 with a weaker adhesion force than an adhesion force between the first insulating layer 2 on the first surface X side and the dicing tape 3. Accordingly, separability from dicing tape 3 is favorable where the first insulating layer 2 is formed.

It is preferable that the first insulating layer 2 is formed on 40% or more and 100% or less of the surface area of the ring-shaped convex area C on the first surface X side. The first insulating layer 2 may not be formed on an area where an outer corner of the ring-shaped convex area C is rounded. The first insulating layer 2 is preferably formed on 50% or more and 100% or less of the flat surface D or/and the approximately flat surface D of the ring-shaped convex area C on the first surface X side, more preferably formed on 60% or more and 100% or less of the flat surface D or/and the approximately flat surface D of the ring-shaped convex area C on the first surface X side, and still more preferably formed on 70% or more and 100% or less of the flat surface D or/and the approximately flat surface D of the ring-shaped convex area C on the first surface X side.

Additionally, a configuration that the flat surface D or/and the approximately flat surface D of the ring-shaped convex area C of the member of FIG. 2 is exposed is also included the embodiment. In this case, the first insulating layer 2 is preferably formed on 60% or more and 90% or less of the flat surface D or/and the approximately flat surface D of the ring-shaped convex area C on the first surface X side, and preferably formed on 70% or more and 90% or less of the flat surface D or/and the approximately flat surface D of the ring-shaped convex area C on the first surface X side. In this case, the first insulating layer 2 is preferably formed on 50% or more and 80% or less of the flat surface D or/and the approximately flat surface D of the ring-shaped convex area C on the first surface X side, more preferably formed on 60% or more and 80% or less of the flat surface D or/and the approximately flat surface D of the ring-shaped convex area C on the first surface X side, and preferably formed on 70% or more and 80% or less of the flat surface D or/and the approximately flat surface D of the ring-shaped convex area C on the first surface X side.

A thickness of the first insulating layer 2 on the ring-shaped convex area C (a distance between R to G in FIG. 4) is preferably 10 [nm] or more and 3 [μm] or less.

A thickness of the first insulating layer 2 on the slope area B (an average thickness of the first insulating layer 2 from the surface of the slope area B toward the vertical direction of the surface of the slope area) is preferably 10 [nm] or more and 3 [μm] or less.

The thickness of the first insulating layer 2 on the ring-shaped convex area C is preferably 1 times or more of the thickness of the first insulating layer 2 on the slope area B, more preferably 1.2 times or more and 3 times or less of the thickness of the first insulating layer 2 on the slope area B.

It is preferable that the first insulating layer 2 is a continuous layer from the ring-shaped convex area C side to the slope area B. A thickness of the first insulating layer 2 of the interface E between the surface of the ring-shaped convex area C and the slope area B is preferably 10 [nm] or more. A thickness of the first insulating layer 2 of the interface E between the surface of the ring-shaped convex area C and the slope area B is preferably 10 [nm] or more and 3 [μm] or less.

The first insulating layer 2 is preferably formed on 1% or more and 100% or less of the surface of the slope area B, more preferably formed on 5% or more and 80% or less of the surface of the slope area B, and more preferably formed on 10% or more and 50% or less of the surface of the slope area B.

When the slope angle R is 20 [°] or more and less than 30 [°], the first insulating layer 2 is preferably formed on 1% or more and 80% or less of the surface of the slope area B, more preferably formed on 5% or more and 50% or less of the surface of the slope area B, and more preferably formed on 10% or more and 30% or less of the surface of the slope area B.

When the slope angle R is 30 [°] or more and 75 [°] or less, the first insulating layer 2 is preferably formed on 1% or more and 100% or less of the surface of the slope area B, more preferably formed on 20% or more and 80% or less of the surface of the slope area B, and more preferably formed on 30% or more and 50% or less of the surface of the slope area B.

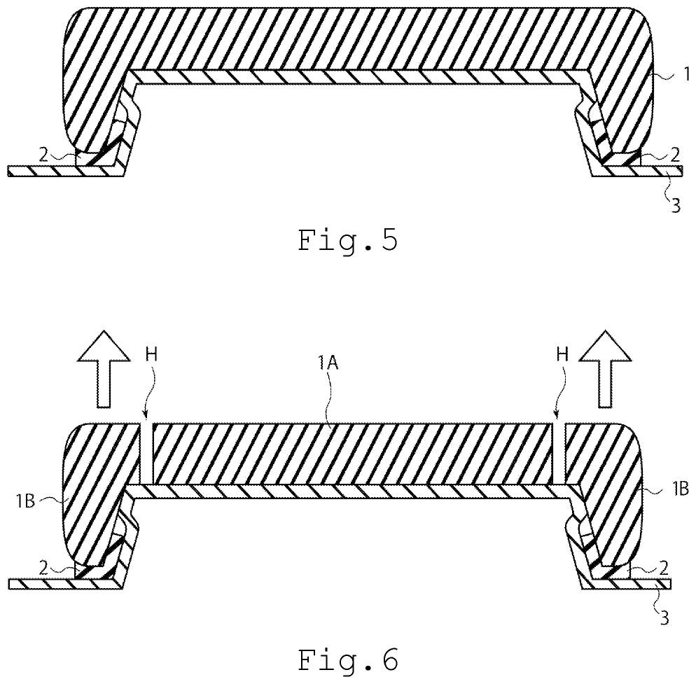

Next, the step of providing the dicing tape 3 on the semiconductor wafer 1 on the first surface X side (second step) will be described with reference to the schematic cross-sectional diagram of FIG. 5. The second step is processed between the first step and the third step.

The dicing tape 3 is provided on the semiconductor wafer 1 on the first surface X side of a member that the first insulating layer 2 is formed on the semiconductor wafer 1 on the first surface X side shown in FIG. 4.

A material of the dicing tape 3 is appropriately selected depending on a cutting method to be applied in a subsequent cutting step. The dicing tape 3 is a tape that protects and holds the semiconductor wafer 1 in the subsequent cutting step.

The dicing tape 3 is in contact with the first insulating layer 2 and the semiconductor wafer 1. When an insulating layer and/or a conductive layer which are not shown in figures on the semiconductor wafer 1 on the first surface X side are provided, the insulating layer and/or the conductive layer which are not shown in figures are in contact with the dicing tape 3. It is preferable that the dicing tape 3 is in direct contact with the first insulating layer 2. The connecting configuration of the member the first insulating layer 2 is formed on the semiconductor wafer 1 on the first surface X side is not limited to the connecting configuration shown in the schematic cross-sectional diagram of FIG. 5 even when the insulating layer and/or the conductive layer which are not shown in figures on the semiconductor wafer 1 on the first surface X side are provided.

An area where the flat surface D or/and the approximately flat surface D of the ring-shaped convex area C is in direct contact with the dicing tape 3 is preferably 0% or more and 20% or less of the surface of the flat surface D or/and the approximately flat surface D of the ring-shaped convex area C, more preferably 0% or more and 10% or less of the surface of the flat surface D or/and the approximately flat surface D of the ring-shaped convex area C, more preferably 0% or more and 5% or less of the surface of the flat surface D or/and the approximately flat surface D of the ring-shaped convex area C, and still more preferably 0% or more and 3% or less of the surface of the flat surface D or/and the approximately flat surface D of the ring-shaped convex area C.

The where the flat surface D or/and the area approximately flat surface D of the ring-shaped convex area C is in direct contact with the dicing tape 3 is preferably 1% or more and 20% or less of the surface of the flat surface D or/and the approximately flat surface D of the ring-shaped convex area C, more preferably 1% or more and 10% or less of the surface of the flat surface D or/and the approximately flat surface D of the ring-shaped convex area C, and still more preferably 1% or more and 5% or less of the surface of the flat surface D or/and the approximately flat surface D of the ring-shaped convex area C.

Next, the step of dividing the semiconductor wafer 1 into a first member of the ring-shaped convex area C and the slope area B and a second member of the concave area A by cutting the semiconductor wafer 1 (third step) will be described with reference to the schematic cross-sectional diagram of FIG. 6. The third step is processed between the second step and the fourth step.

The semiconductor wafer is cut by, for example, blade dicing or laser dicing. The cutting of the third step is not individualization, which cuts the semiconductor device into individual chips. In the third step, the position of the concave area A on the slope area B side is cut in a circular-like shape (circular or abbreviated circular). By cutting the semiconductor wafer 1, it is separated into a doughnut-shaped member 1 B (first member), in which the ring-shaped convex area C and the slope area B are integrated, and a disc-shaped member 1A (second member), which includes the concave area A of the semiconductor wafer 1.

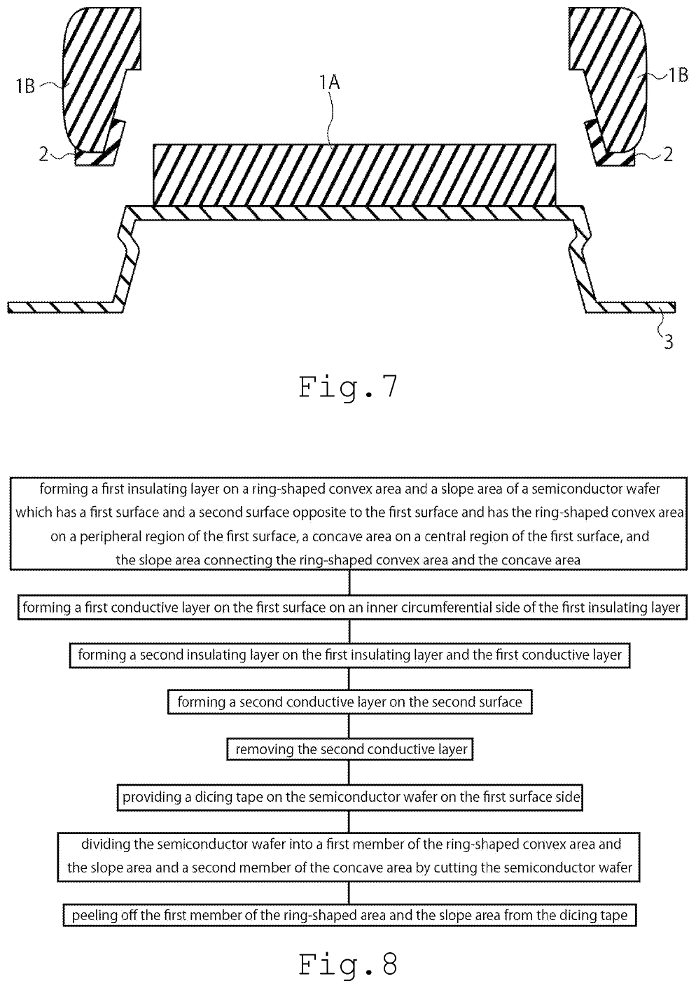

Next, the step of peeling off the first member of the ring-shaped convex area C and the slope area B from the dicing tape 3 (fourth step) will be described with reference to the schematic cross-sectional diagrams of FIG. 6 and FIG. 7. The fourth step is processed after the third step.

The doughnut-shaped member 1B, in which the ring-shaped convex area C and the slope area B are integrated, is peeled off from the dicing tape 3 by, for example, lifting of the doughnut-shaped member 1B (rim part) of the member which are cut shown in FIG. 6.

By virtue of the first insulating layer 2 which is formed on the flat surface D or/and the approximately flat surface D, the ring-shaped convex area C and the slope area B, that is the divided doughnut-shaped member 1B, can be separated from the dicing tape 3 with weak force. When the separation is processed with the weak force, it is possible to reduce damage such as breaking of the semiconductor wafer 1 in the concave area A, which is the disc-shaped member 1A, during the separation process.

From the viewpoint of reducing damage to the semiconductor wafer 1 on the concave area A side when peeling off the ring-shaped convex area C and the slope area B (first member) of the semiconductor wafer 1 in which the first insulating layer 2 is formed from the dicing tape, the slope angle R is preferably 20 [°] or more and 75 [°] or less, and more preferably 30 [°] or more and 60 [°] or less.

From the viewpoint of reducing damage to the semiconductor wafer 1 on the concave area A side when peeling off the ring-shaped convex area C and the slope area B of the semiconductor wafer 1 in which the first insulating layer 2 is formed from the dicing tape, the thickness of the first insulating layer 2 on the ring-shaped convex area C is preferably 10 [nm] or more and 3 [μm] or less.

From the viewpoint of reducing to damage the semiconductor wafer 1 on the concave area A side when peeling off the ring-shaped convex area C and the slope area B of the semiconductor wafer 1 in which the first insulating layer is formed from the dicing tape 3, the thickness of the first insulating layer 2 on the slope area B is preferably 10 [nm] or more and 3 [μm] or less.

The higher the average roughness height of the ring-shaped convex area C on the first surface X side, the stronger the adhesion force between the dicing tape 3 and the semiconductor wafer 1.

From the viewpoint of reducing damage to the semiconductor wafer 1 on the concave area A side when peeling off the ring-shaped convex area C and the slope area B (first member) of wafer the semiconductor 1 on which the first insulating layer 2 is formed from the dicing tape 3 when the average roughness height on the first surface X side of the ring-shaped convex area C is between 5 [nm] and 30 [nm], the thickness of the first insulating layer 2 on the ring-shaped convex area C is preferably 50 [nm] or more and 3 [μm] or less, more preferably 100 [nm] or more and 2 [μm] or less, and still more preferably 200 [nm] or more and 1 [μm] or less when the average roughness height of the ring-shaped convex area C on the first surface X side is [5 nm] or more and 30 [nm] or less.

From the viewpoint of reducing damage to the semiconductor wafer 1 on the concave area A side when peeling off the ring-shaped convex area C and the slope area B of the semiconductor wafer 1 on which the first insulating layer 2 is formed from the dicing tape 3 when the average roughness height on the first surface X side of the ring-shaped convex area C is between 5 [nm] and 30 [mm], the thickness of the first insulating layer 2 on the slope area B is preferably 50 [nm] or more and 3 [μm] or less, more preferably 100 [nm] or more and 2 [μm] or less, and still more preferably 200 [nm] or more and 1 [μm] or less when the average concavo-convexity height of the ring-shaped convex area C on the first surface X side is 5 [nm] or more and 30 [nm] or less.

The semiconductor device (e.g., bare chips) can be manufactured by some additional optional process after the fourth step.

By virtue of applying the manufacturing method for the semiconductor device, separability of the dicing tape 3 is improved, the damage of the semiconductor wafer 1 including the concave area A where the effective area for the semiconductor device is formed is reduced, and it contributes improving yield in the semiconductor device manufacturing.

### Second Embodiment

A manufacturing method for a semiconductor device according to a second embodiment includes forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area (first step), forming a first conductive layer on the first surface on an inner circumferential side of the first insulating layer (fifth step), forming a second insulating layer on the first insulating layer and the first conductive layer (sixth step), forming a second conductive layer on the second surface (seventh step), removing the second conductive layer (eighth step), providing a dicing tape on the semiconductor wafer on the first surface side (second step), dividing the semiconductor wafer into a first member of the ring-shaped convex area and the slope area and a second member of the concave area by cutting the semiconductor wafer (third step), and peeling off the first member of the ring-shaped area and the slope area from the dicing tape (fourth step).

The second embodiment relates to a manufacturing method for the semiconductor device. The manufacturing method for the semiconductor device according to the second embodiment is a variation of the manufacturing method for the semiconductor device according to the first embodiment. The manufacturing method for a semiconductor device according to the second embodiment is more specific than the manufacturing method for the semiconductor device according to the first embodiment. The description of the common contents of the first embodiment and the second embodiment will be omitted.

FIG. 8 is a flowchart for a manufacturing method for the semiconductor device according to the first embodiment. FIG. 2 to FIG. 7 show schematic cross-sectional diagrams and a schematic process diagram of top view for a manufacturing method for the semiconductor device according to the first embodiment.

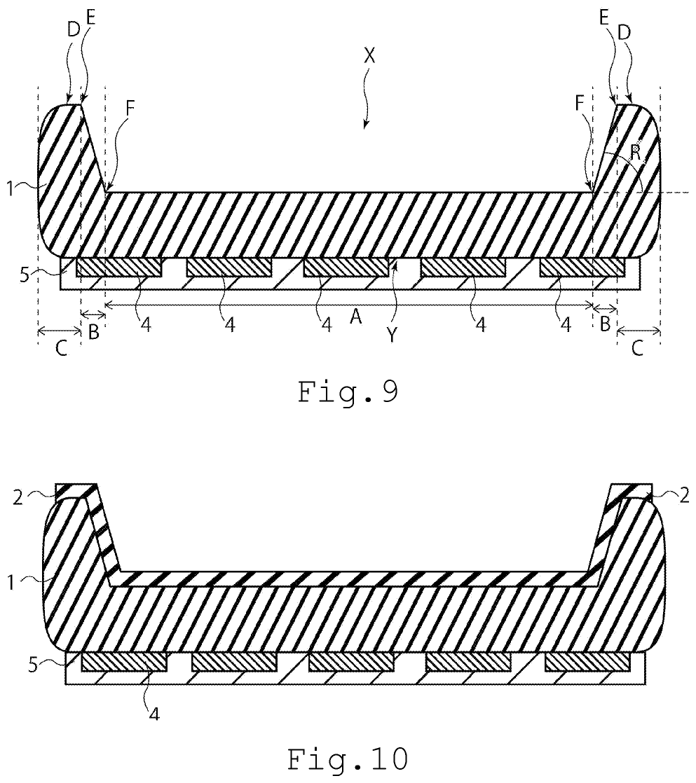

The step of forming the first insulating layer 2 on the ring-shaped convex area C and the slope area B of the semiconductor wafer 1 which has the first surface X and the second surface Y opposite to the first surface X and has the ring-shaped convex area C on the peripheral region of the first surface X, the concave area A on the central region of the first surface X, and the slope area B connecting the ring-shaped convex area C and the concave area A (first step) will be described with reference to the schematic cross-sectional diagrams of FIG. 9 to FIG. 13.

In the first step of the second embodiment, the first insulating layer 2 is formed on the ring-shaped convex area C and the slope area B by preparing the first insulating layer 2 on the entire semiconductor wafer 1 on the first surface X side and processing.

First, the first insulating layer 2 is formed entirely on the member shown in the schematic cross-sectional diagram in FIG. 9, and the member shown in the schematic cross-sectional diagram in FIG. 10 is obtained. Electrode pads 4 and a protection layer 5 is provided on the member shown in the schematic cross-sectional diagram shown in FIG. 9 on the second surface Y side.

The electrode pad 4 is, for example, a conductive metal layer that electrically connects to the semiconductor device. The electrode pad 4 is an electrode of the semiconductor device.

The protection layer 5 is an insulating layer which covers the electrode pads 4. It is preferable that the electrode pads 4 is not exposed on a surface of the protection layer 5. The protection layer 5 is an insulating layer which is mainly composed of polyethylene, naphthalene, polyolefin, polyethylene terephthalate, or the like.

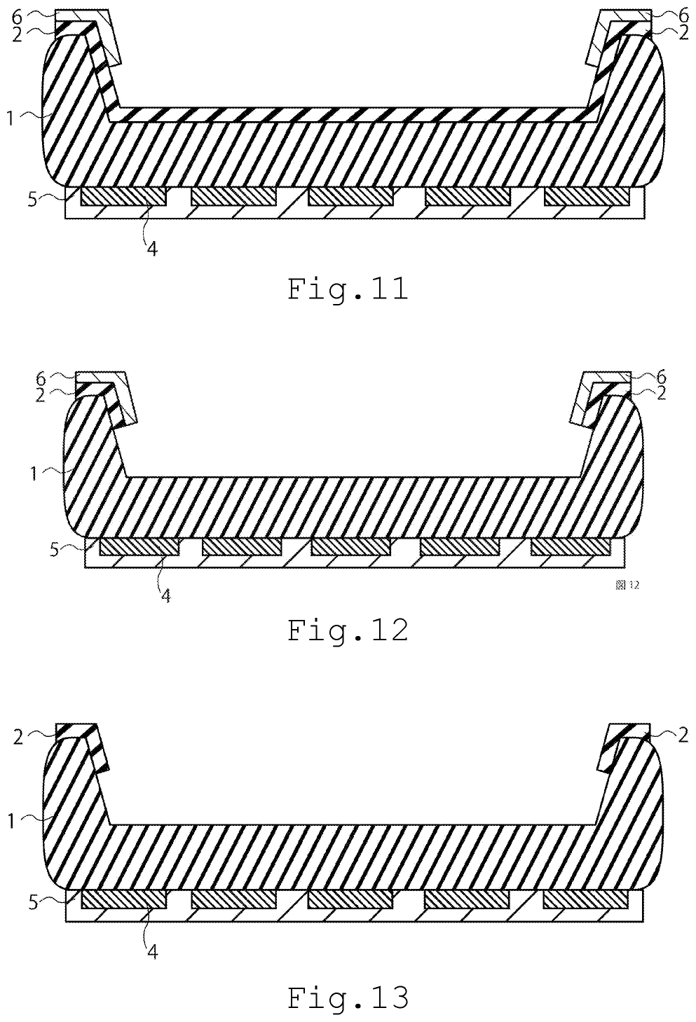

A resist (mask) 6 is formed after forming the first insulating layer 2 entirely on the semiconductor wafer 1 on the first surface X side, and the member shown in the schematic cross-sectional diagram in FIG. 11 is obtained. The first insulating layer 2 is formed by, for example, depositing SiO₂ by plasma CVD. A depositing temperature is, for example, 200 [° C.] or less, considering heat resistance of the protection layer 5.

Next, the first insulating layer 2 is processed with using the resist 6 of the member of the schematic process diagram of FIG. 11, the first insulating layer 2 that is formed on the concave area A and part of the first insulating layer 2 that is formed on the slope area B is removed, and the member shown in the schematic cross-sectional diagram in FIG. 12 is obtained. For example, the first insulating layer 2 that is a SiO₂ layer is processed by wet-etching, and the first insulating layer 2 in the portion where the resist 6 is not formed is removed.

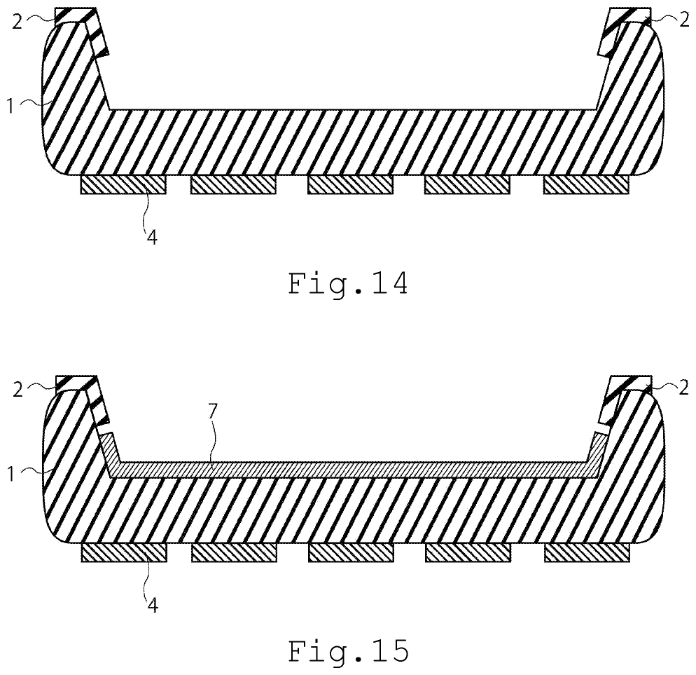

Next, the resist 6 of the member shown in the schematic cross-sectional diagram in FIG. 12 is removed, and the member shown in the schematic cross-sectional diagram in FIG. 13 is obtained.

The step of forming a first conductive layer 7 on the first surface X on the inner circumferential side of the first insulating layer 2 (fifth step) will be described with reference to the schematic cross-sectional diagrams of FIG. 14 to FIG. 15.

The fifth step is a step of forming the first conductive layer 7 on the first surface X on the inner circumferential side of the first insulating layer 2 where the first insulating layer 2 is not formed. The fifth step is processed between the first step and the sixth step.

The protection layer 5 of the member of the schematic cross-sectional diagram of FIG. 13 is removed as shown in the schematic cross-sectional diagram of FIG. 14. The protection layer 5 is removed by peeling off or other method. After removing the protection layer 5, furnace annealing is preferably processed.

Next, the first conductive layer 7 is formed on the first surface X of the circumferential side of the first insulating layer 2 of the member of the schematic cross-sectional diagram where the first insulating layer 2 is not formed, and the member shown in the schematic cross-sectional diagram of FIG. 15 is obtained.

The first conductive layer 7 is formed so that the first conductive layer 7 does not overlap the first insulating layer 2. The first insulating layer 2 may be in direct contact with the first conductive layer 7 or may be separated to the first conductive layer 7 (the first insulating layer 2 may not be in direct contact with the first conductive layer 7). It is preferable that the first conductive layer 7 and the first insulating layer 2 are not stacked in a stacking direction of the first insulating layer 2 and the semiconductor wafer 1 (a stacking direction of the first insulating layer 2 and the semiconductor wafer 1 shown in FIG. 15) even when the first insulating layer 2 is in direct contact with the first conductive layer 7 in a plane direction of the first surface X. It is not preferable that the first conductive layer 7 is easy to peel off at the interface of the stacked portion if the first conductive layer 7 is stacked on the first insulating layer 2.

It is preferable that a surface of the first insulating layer 2 formed on the ring-shaped convex area C which is opposite to a surface of the first insulating layer 2 facing to the semiconductor wafer 1 and is not in direct contact with the first conductive layer 7. Additionally, it is preferable that a surface of the first insulating layer 2 formed on the slope area B which is opposite to a surface of the first insulating layer 2 facing to the semiconductor wafer 1 and is not in direct contact with the first conductive layer 7.

A distance between the first insulating layer 2 and the first conductive layer in a plane direction of the first surface X is preferably 0.0 [mm] or more and 2.0 [mm] or less, and more preferably 0.0 [mm] or more and 1.0 [mm] or less.

From the viewpoint of forming the first conductive layer 7 so that the first conductive layer 7 is not stacked on the first insulating layer 2, the distance between the first insulating layer 2 and the first conductive layer 7 in the plane direction of the first surface X is 0.1 [mm] or more and 2.0 [mm] or less, and more preferably 0.2 [mm] or more and 1.0 [mm] or less.

It is preferable to use an outer circumference cover covering the first insulating layer 2 so that the first conductive layer 7 is not stacked on the first insulating layer 2. The outer circumference cover includes a circular opening, and a metal layer may be deposited in a region of the opening. The outer circumference cover is, for example, a susceptor or a clamp.

It is preferable that the first conductive layer 7 is a continuous layer which does not include opening and does not be divided.

The step of forming a second insulating layer 8 on the first insulating layer 2 and the first conductive layer 7 (sixth step) will be described with reference to the schematic cross-sectional diagram of FIG. 16.

The sixth step is a step of forming the second insulating layer 8 on the first insulating layer 2 and the first conductive layer 7 that is entire side of the first surface X of the semiconductor wafer 1. The sixth step is processed between the fifth step and the seventh step.

The second insulating layer 8 is formed on the member shown in the schematic cross-sectional diagram of FIG. 15. Before processing the sixth step, the first insulating layer 2 is formed on the ring-shaped convex area C, and the ring-shaped convex area C is already covered sufficiently. Then, the second insulating layer 8 is formed without much concern for coverage of the first insulating layer 2 and the first conductive layer 7.

Since the interface E between the flat surface D or/and the approximately flat surface D of the ring-shaped convex area C and the slope area B is covered with the first insulating layer 2, the second insulating layer 8 is preferably formed so that the surface of the first conductive layer 7 is not exposed.

Since the interface E between the flat surface D or/and the approximately flat surface D of the ring-shaped convex area C and the slope area B is covered with the first insulating layer 2, the second insulating layer 8 is preferably formed so that the second insulating layer 8 covers a gap area of the surface of the semiconductor wafer 1 between the first layer insulating and the first 2 conductive layer 7. The second insulating layer 8 may be filled in the gap area between the first insulating layer 2 and the first conductive layer 7 as shown in the schematic cross-sectional diagram of FIG. 15.

The second insulating layer 8 is preferably an inorganic insulating film, a resin insulating film, or an insulating film containing an inorganic insulator and resin.

The second insulating layer 8 is, for example, a coated layer, but may be a layer which is formed by other methods.

The first insulating layer 2 and the second insulating layer 8 covers the entirely of the semiconductor wafer 1 on the first surface X side. Accordingly, it is preferable that extraneous deposition on the semiconductor wafer 1 and/or the first conductive layer 7 can be reduced or disappeared in the following seventh step.

When the fifth step is omitted, the second insulating layer 8 is formed on an open surface of the semiconductor wafer 1 on the first surface X side.

When the electrodes are not formed on both surfaces of the semiconductor wafer 1 after forming the first insulating layer 2, the fifth step, the sixth step, the seventh step, and the eighth step is omitted.

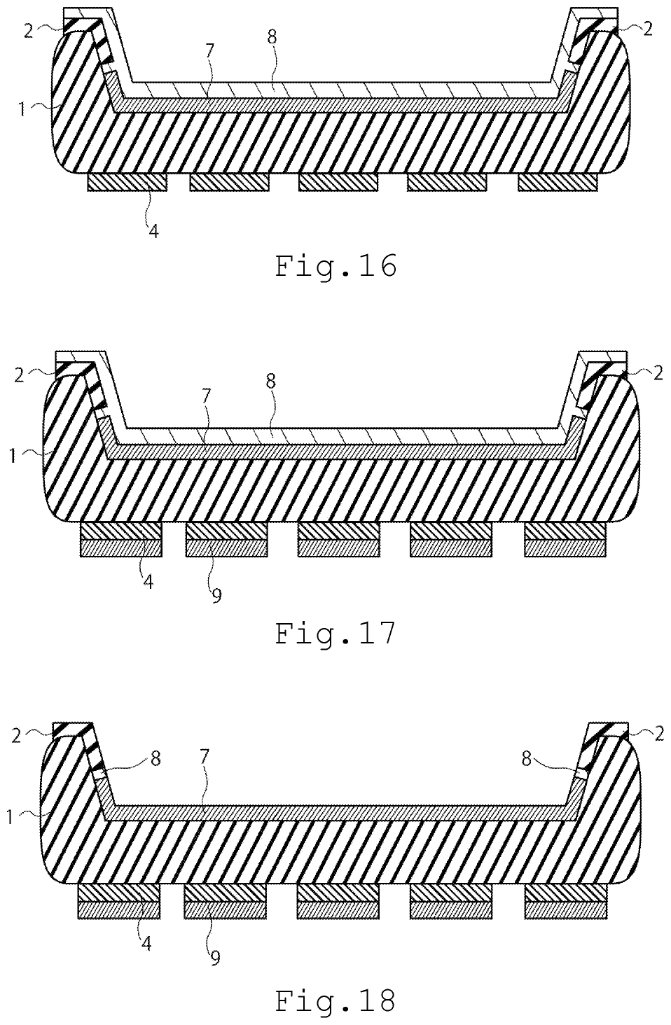

The step of forming the second conductive layer 9 on the second surface Y (seventh step) will be described with reference to the schematic cross-sectional diagram of FIG. 17.

The seventh step is a step of forming the second conductive layer 9 on the electrode pad 4 on the second surface Y side by electroless plating or other method. The seventh step is processed between the sixth step and the eight step.

The step of removing the second conductive layer 9 (eighth step) will be described with reference to the schematic cross-sectional diagrams of FIG. 18 and FIG. 19.

The eighth step is a step of removing the second insulating layer 8 on the first surface X side by peeling off or other method. The eighth step is processed between the seventh step and the second step.

When the second insulating layer 8 is formed on the gap between the first insulating layer 2 and the first conductive layer 7 at the time of the sixth step being processed, the second insulating layer 8 may remain in the gap between the first insulating layer 2 and the first conductive layer 7 as shown in the schematic cross-sectional diagram of FIG. 18 or the second insulating layer 8 which presents in the gap between the first insulating layer 2 and the first conductive layer 7 may be removed.

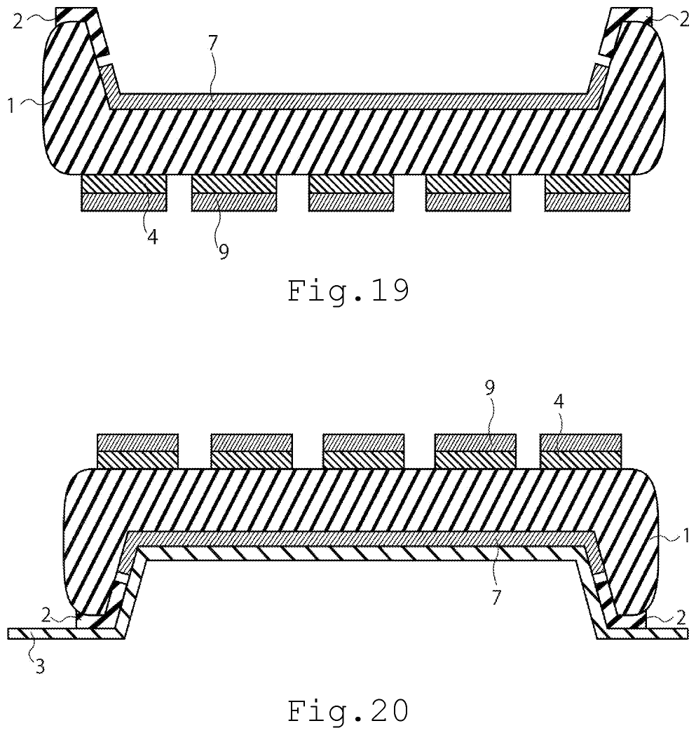

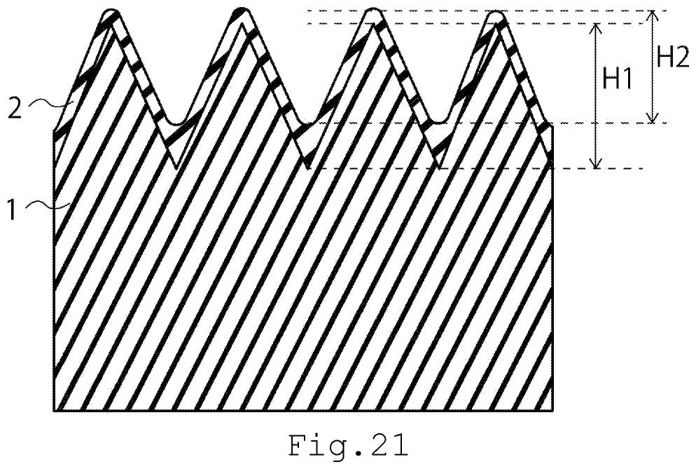

Next, the step of providing the dicing tape 3 on the semiconductor wafer 1 on the first surface X side (second step) will be described with reference to the schematic cross-sectional diagram of FIG. 20. The second step is processed between the eighth step and the third step.

The dicing tape 3 is pasted on the semiconductor wafer 1 on the first surface X side as described in the first embodiment. Further, the third step and the fourth step are processed as described in the first embodiment, and the semiconductor device can be manufactured.

By virtue of applying the manufacturing method for the semiconductor device, separability of the dicing tape 3 is improved, the damage of the semiconductor wafer 1 including the concave area A where the effective area for the semiconductor device is formed is reduced, and it contributes improving yield in the semiconductor device manufacturing. Additionally, the extraneous deposition can be reduced in plating the second conductive layer 9, and it contributes improving yield in the semiconductor device manufacturing.

### Third Embodiment

A manufacturing method for a semiconductor device according to a the embodiment includes forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area (first step), forming a first conductive layer on the first surface on an inner circumferential side of the first insulating layer (fifth step), forming a second insulating layer on the first insulating layer and the first conductive layer (sixth step), forming a second conductive layer on the second surface (seventh step), removing the second conductive layer (eighth step), providing a dicing tape on the semiconductor wafer on the first surface side (second step), dividing the semiconductor wafer into a first member of the ring-shaped convex area and the slope area and a second member of the concave area by cutting the semiconductor wafer (third step), and peeling off the first member of the ring-shaped area and the slope area from the dicing tape (fourth step).

The third embodiment relates to a manufacturing method for a semiconductor device. The manufacturing method for the semiconductor according device to the third embodiment is a variation of the manufacturing method for the semiconductor device according to the first embodiment or/and the second embodiment. The manufacturing method for a semiconductor device according to the third embodiment is more specific than the manufacturing method for the semiconductor device according to the first embodiment. The description of the common contents of the first embodiment to the third embodiment will be omitted.

In the description of the manufacturing method for the semiconductor the third embodiment, the device of flowchart and schematic cross-sectional diagram of the manufacturing method for the semiconductor device of the second embodiment will be partially referred in the description.

The step of forming the first insulating layer 2 on the ring-shaped convex area C and the slope area B of the semiconductor wafer 1 which has the first surface X and the second surface Y opposite to the first surface X and has the ring-shaped convex area C on the peripheral region of the first surface X, the concave area A on a central region of the first surface X, and the slope area B connecting the ring-shaped convex area C and the concave area A (first step) will be described with reference to the schematic cross-sectional diagrams of FIG. 9 and FIG. 13.

The first insulating layer 2 is formed on the member shown in the schematic cross-sectional diagram of FIG. 9 by inkjet, and the member shown in the schematic cross-sectional diagram is obtained.

The step of forming the first conductive layer 7 on the first surface X on the inner circumferential side of the first insulating layer 2 (fifth step) will be described with reference to the schematic cross-sectional diagrams of FIG. 14 and FIG. 15.

The protection layer 5 of the member shown in the schematic cross-sectional diagram of FIG. 13 is removed as shown in the schematic cross-sectional diagram of FIG. 14. The protection layer 5 is removed by peeling off other method. After removing the protection layer 5, furnace annealing is preferably processed, and the first insulating layer 2 is preferably annealed (hardened).

Additionally, the first conductive layer 7 is formed on the member shown in the schematic cross-sectional diagram of FIG. 14 by sputtering, and the member shown in the schematic cross-sectional diagram of FIG. 15 is obtained.

Furthermore, the eighth step and the second step to the fourth step are processed, and the semiconductor device can be manufactured preferably.

Referring to the partial schematic cross-sectional diagram of semiconductor wafer 1 shown in FIG. 21, the roughness of the flat surface D and/or the concavity of the flat surface D or/and the approximately flat surface D of the ring-shaped convex area C common to the first, second and third embodiments will be explained. FIG. 21 is a partial cross-sectional schematic diagram of the b-b′ section of FIG. 3.

The partial schematic cross-sectional diagram of semiconductor wafer 1 and first insulating layer 2 in FIG. 21 shows a roughness height (average value) of the flat surface D or/and flat the approximately surface D of the ring-shaped convex area C of semiconductor wafer 1 itself is represented as H1, and a roughness height (average value) of the flat surface D or/and the approximately flat surface D of the ring-shaped convex area C after forming first insulating layer 2 is represented as H2. The roughness height H1 is larger when the slope area B and the concave area A are formed by wet etching.

The roughness height H2 is reduced compared to the roughness height H1. The cross-section becomes arc-shape (the center of the arc is located in the direction towards the first insulating layer 2 from the semiconductor wafer than the arc) so that the first insulating layer 2 on the bottom side of the concave area A is thick regardless of the shapes (flatness/roughness) of the upper side and the bottom side of the roughness even when the thickness of the first insulating layer 2 which is formed on a slope surface of the roughness is the same, and the cross-section becomes arc-shape (The center of the arc is located in the direction towards the first insulating layer 2 from the semiconductor wafer 1 than the arc) so that thickness of the first insulating layer 2 of the upper side of the concave area is thin. When the dicing tape 3 is provided on the entirely of the ring-shaped convex area C of the semiconductor wafer 1, the adhesion force between the semiconductor wafer 1 and the dicing tape since H1 is high, and breaking in the concave are A of the semiconductor wafer 1 may be easy to occur in the dividing of the fourth step.

After forming the first insulating layer 2, the adhesion force between dicing tape and the the 3 semiconductor wafer 1 is reduced since the roughness height H2 of the flat surface D or and the approximately flat surface D of the ring-shaped convex area C becomes smaller than the roughness height H2 even if the roughness surface of the ring-shaped convex area C of the semiconductor wafer 1 is partly exposed, and it contributes that the breaking of the concave area A of the semiconductor wafer 1 in the dividing of the fourth step is reduced.

According to the embodiment, the first insulating layer 2 is also formed on the interface between the ring-shaped convex area C and the slope area B since the slope area B exists, it preferably contributes that the adhesion force between the semiconductor wafer 1 and the dicing tape 3 at the interface E between the ring-shaped convex area C and the slope area B is reduced.

According to the embodiment, the first insulating layer 2 is also formed on the interface E between the ring-shaped convex area C and the slope area B since the slope area B exists, it preferably contributes that the extraneous deposition is reduced in the seventh step.

Further, by virtue of forming the second insulating layer 8 on the surface where the roughness of the flat surface D or/and the approximately flat surface D of the ring-shaped convex area c is mitigated, the roughness is further mitigated, and it preferably contributes that the adhesion force between the dicing tape 3 and the semiconductor wafer 1 is decreased.

When the slope angle R is reduced, it is conceivable that the second insulating layer 8 may suitably mitigate the above roughness without forming the first insulating layer 2 due to the gradual slope. However, as the slope angle R is reduced, the area of the slope area B viewed from the first surface X side of the semiconductor wafer 1 increases. This reduces the effective area of the semiconductor wafer 1, which is economically undesirable. In this case, the effective area of the semiconductor wafer 1 can be increased by reducing the are of the flat surface D or/and the approximately flat surface D of the ring-shaped convex area C. However, in this case, the strength of the semiconductor wafer 1 due to the rim shape is decreased due to the smaller ring-shaped convex area C, which is not practical and is not desirable.

From the above viewpoint, the slope angle R is preferably 20 [°] or more and 75 [°] or less, and more preferably 30 [°] or more and 60 [°] or.

By virtue of applying the configuration of the embodiment, it is preferable to achieve a good balance between the strength of the semiconductor wafer 1, the large effective area of the semiconductor wafer 1, and the reduction of breaking in the semiconductor wafer 1 when the semiconductor wafer 1 is peeled off from the dicing tape 3.

By virtue of applying the configuration of the embodiment, it is preferable to be able to reduce the extraneous deposition when forming the second conductive layer 9 while achieving the above effects.

Hereinafter, clauses of embodiments are additionally noted.

### Clause 1

A manufacturing method for a semiconductor device comprising:
forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area;
providing a dicing tape on the semiconductor wafer on the first surface side;
dividing the semiconductor wafer into a first member of the ring-shaped convex area and the slope area and a second member of the concave area by cutting the semiconductor wafer; and
peeling off the first member of the ring-shaped area and the slope area from the dicing tape.

### Clause 2

The method according to clause 1,
Wherein the first insulating layer is an inorganic insulating layer.

### Clause 3

The method according to clause 1 or 2,
wherein a thickness of the first insulating layer the ring-shaped convex area is 10 [nm] or more and 3 [μm] or less.

### Clause 4

The method according to any one of clauses 1 to 3,
wherein a thickness of the first insulating layer on the slope area is 10 [nm] or more and 3 [μm] or less.

### Clause 5

The method according to any one of clauses 1 to 4,
wherein a flat surface or/and an approximately flat surface exists on the semiconductor wafer on the first surface side, and
the first insulating layer is formed on 50% or more and 100% or less of the flat surface or/and the approximately flat surface.

### Clause 6

The method according to any one of clauses 1 to 5,
wherein a flat surface or/and an approximately flat surface exists on the semiconductor wafer on the first surface side, and
the first insulating layer is formed on 50% or more and 90% or less of the flat surface or/and the approximately flat surface.

### Clause 7

The method according to any one of clauses 1 to 6,
wherein a thickness of the first insulating layer on the ring-shaped convex area is 1.2 times or more and 3 times or less of a thickness of the first insulating layer on the slope area.

### Clause 8

The method according to any one of clauses 1 to 7,
wherein the first insulating layer is formed on 1% or more and 100% or less of the surface of the slope area.

### Clause 9

The method according to any one of clauses 1 to 8,
wherein a slope angle of the slope area is 20 [°] or more and 75 [°] or less.

### Clause 10

The method according to any one of clauses 1 to 9,
wherein when a slope angle of the slope area is 20 [°] or more and less than 30 [°], the first insulating layer is formed on 1% or more and 80% or less of a surface of the slope area.

### Clause 11

The method according to any one of clauses 1 to 10,
wherein when a slope angle of the slope area is 30 [°] or more and 75 [°] or less, the first insulating layer is formed on 1% or more and 80% or less of a surface of the slope area.

### Clause 12

The method according to any one of clauses 1 to 10,
wherein when an average roughness height on the first surface side of the ring-shaped convex area is between 5 [nm] and 30 [nm], the thickness of the first insulating layer on the ring-shaped convex area is 50 [nm] or more and 3 [μm] or less.

### Clause 13

The method according to any one of clauses 1 to 12,
wherein when an average roughness height on the first surface side of the ring-shaped convex area is between 5 [nm] and 30 [nm], the thickness of the first insulating layer on the slope area is 50 [nm] or more and 3 [μm] or less.

### Clause 14

The method according to any one of clauses 1 to 13,
wherein when an average roughness height on the first surface side of the ring-shaped convex area is between 5 [nm] and 30 [nm], the thickness of the first insulating layer on the ring-shaped convex area is 50 [nm] or more and 3 [μm] or less, and the thickness of the first insulating layer on the slope area is 50 [nm] or more and 3 [μm] or less.

### Clause 15

The method according to any one of clauses 1 to 14,
wherein the first insulating layer is formed by plasma CVD on the semiconductor wafer on the first surface side,
a depositing temperature of the first insulating layer by plasma CVD is 200[° C.] or less, and
the first insulating layer which is formed entirely is processed by wet-etching with using the resist.

### Clause 16

The method according to any one of clauses 1 to 15, further comprising between the forming the first insulating layer and the providing the dicing tape:
forming a first conductive layer on the first surface on an inner circumferential side of the first insulating layer;
forming a second insulating layer on the first insulating layer and the first conductive layer;
forming a second conductive layer on the second surface; and
removing the second conductive layer.

### Clause 17

The method according to clause 16,
wherein the first conductive layer is formed by sputtering so that the first conductive layer is not stacked on the first insulating layer.

### Clause 18

The method according to clause 16 or 17,
wherein the second conductive layer by electroless plating.

### Clause 19

The method according to any one of clauses 16 to 18,
wherein a distance between the first insulating layer and the first conductive layer in a plane direction of the first surface is 0.0 [mm] or more and 2.0 [mm] or less.

### Clause 20

The method according to any one of clauses 16 to 19,
wherein a distance between the first insulating layer and the first conductive layer in a plane direction of the first surface is 0.1 [mm] or more and 2.0 [mm] or less.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a semiconductor device comprising:
forming a first insulating layer on a ring-shaped convex area and a slope area of a semiconductor wafer which has a first surface and a second surface opposite to the first surface and has the ring-shaped convex area on a peripheral region of the first surface, a concave area on a central region of the first surface, and the slope area connecting the ring-shaped convex area and the concave area;
providing a dicing tape on the semiconductor wafer on the first surface side;
dividing the semiconductor wafer into a first member of the ring-shaped convex area and the slope area and a second member of the concave area by y cutting the semiconductor wafer; and
peeling off the first member of the ring-shaped area and the slope area from the dicing tape.

2. The method according to claim 1,
wherein the first insulating layer is an inorganic insulating layer.

3. The method according to claim 1,
wherein a thickness of the first insulating layer on the ring-shaped convex area is 10 [nm] or more and 3 [μm] or less.

4. The method according to claim 1,
wherein a thickness of the first insulating layer on the slope area is 10 [nm] or more and 3 [μm] or less.

5. The method according to claim 1,
wherein a flat surface or/and an approximately flat surface exists on the semiconductor wafer on the first surface side, and
the first insulating layer is formed on 50% or more and 100% or less of the flat surface or/and the approximately flat surface.

6. The method according to claim 1,
wherein a flat surface or/and an approximately flat surface exists on the semiconductor wafer on the first surface side, and
the first insulating layer is formed on 50% or more and 90% or less of the flat surface or/and the approximately flat surface.

7. The method according to claim 1,
wherein a thickness of the first insulating layer on the ring-shaped convex area is 1.2 times or more and 3 times or less of a thickness of the first insulating layer on the slope area.

8. The method according to claim 1,
wherein the first insulating layer is formed on 1% or more and 100% or less of the surface of the slope area.

9. The method according to claim 1,
The method according to any one of clauses 1 to 8,
wherein a slope angle of the slope area is 20 [°] or more and 75 [°] or less.

10. The method according to claim 1,
wherein when a slope angle of the slope area is 20 [°] or more and less than 30 [°], the first insulating layer is formed on 1% or more and 80% or less of a surface of the slope area.

11. The method according to claim 1,
wherein when a slope angle of the slope area is 30 [°] or more and 75 [°] or less, the first insulating layer is formed on 1% or more and 80% or less of a surface of the slope area.

12. The method according to claim 1,
wherein when an average roughness height on the first surface side of the ring-shaped convex area is between 5 [nm] and 30 [nm], the thickness of the first insulating layer on the ring-shaped convex area is 50 [nm] or more and 3 [μm] or less.

13. The method according to claim 1,
The method according to any one of clauses 1 to 12,
wherein when an average roughness height on the first surface side of the ring-shaped convex area is between 5 [nm] and 30 [nm], the thickness of the first insulating layer on the slope area is 50 [nm] or more and 3 [μm] or less.

14. The method according to claim 1,
wherein when an average roughness height on the first surface side of the ring-shaped convex area is between 5 [nm] and 30 [nm], the thickness of the first insulating layer on the ring-shaped convex area is 50 [nm] or more and 3 [μm] or less, and the thickness of the first insulating layer on the slope area is 50 [nm] or more and 3 [μm] or less.

15. The method according to claim 1,
wherein the first insulating layer is formed by plasma CVD on the semiconductor wafer on the first surface side,
a depositing temperature of the first insulating layer by plasma CVD is 200 [° C.] or less, and
the first insulating layer which is formed entirely is processed by wet-etching with using the resist.

16. The method according to claim 1, further comprising between the forming the first insulating layer and the providing the dicing tape:
forming a first conductive layer on the first surface on an inner circumferential side of the first insulating layer;
forming a second insulating layer on the first insulating layer and the first conductive layer;
forming a second conductive layer on the second surface; and
removing the second conductive layer.

17. The method according to claim 16,
wherein the first conductive layer is formed by sputtering so that the first conductive layer is not stacked on the first insulating layer.

18. The method according to claim 16,
wherein the second conductive layer by electroless plating.

19. The method according to claim 16,
wherein a distance between the first insulating layer and the first conductive layer in a plane direction of the first surface is 0.0 [mm] or more and 2.0 [mm] or less.

20. The method according to claim 16,
wherein a distance between the first insulating layer and the first conductive layer in a plane direction of the first surface is 0.1 [mm] or more and 2.0 [mm] or less.
